(19) United States
(12) Patent Application Publication
(10) Pub. No.: US 2009/0310324 A1
(43) Pub. Date: Dec. 17, 2009

(54) METHOD OF ELECTRICALLY GROUNDING AN ELECTRICAL SWITCHING APPARATUS AND ELECTRICAL SWITCHING APPARATUS INCLUDING THE SAME

(76) Inventors: Patrick W. Mills, Bradenton, FL (US); Richard G. Benshoff, Sarasota, FL (US); James M. McCormick, Bradenton, FL (US)

Correspondence Address: ECKERT SEAMANS CHERIN & MELLOTT, 600 GRANT STREET, 44TH FLOOR, PITTSBURGH, PA, 15219, US

(21) Appl. No.: 12/139,707

(22) Filed: Jun. 16, 2008

(51) Int. Cl. H01R 4/66; H05K 7/14

(52) U.S. Cl. 361/799; 174/51; 361/753; 200/50.39; 439/103

(57) ABSTRACT

An aircraft circuit breaker includes a housing and a conductive member coupled thereto. The conductive member has a first conductive portion structured to be electrically and mechanically coupled to a conductive panel and a plurality of second conductive portions with a plurality of openings therethrough. An electronic circuit cooperates with an operating mechanism to trip open separable contacts. The circuit includes printed circuit boards having a plurality of conductive pads defining a ground. Each conductive pad has an opening therethrough. Each of a plurality of threaded conductive fasteners includes a conductive end portion, a conductive shaft disposed from the conductive end portion, and a plurality of conductive threads disposed on the conductive shaft. A number of the conductive threads electrically and mechanically engage a corresponding second conductive portion at a corresponding one of the openings. The conductive end portion electrically engages a corresponding one of the conductive pads.

### BACKGROUND OF THE INVENTION

1. Field of the Invention

This invention pertains generally to electrical switching apparatus and, more particularly, to circuit interrupters, such as, for example, aircraft circuit breakers. The invention also pertains to methods of electrically grounding electrical switching apparatus, such as panel-mounted aircraft circuit breakers.

2. Background Information

Circuit breakers are used to protect electrical circuitry from damage due to an overcurrent condition, such as an overload condition or a relatively high level short circuit or fault condition between a power source and a load.

Subminiature circuit breakers are used, for example, in aircraft electrical systems where they not only provide overcurrent protection but also serve as switches for turning equipment on and off. As such, they are subjected to heavy use and, therefore, must be capable of performing reliably over many operating cycles. They also must be relatively small to accommodate the high-density layout of circuit breaker panels, which make circuit breakers for numerous circuits accessible to a user. Aircraft electrical systems usually consist of hundreds of circuit breakers, each of which is used for a circuit protection function as well as a circuit disconnection function through a push-pull handle.

Typically, subminiature circuit breakers have only provided protection against persistent overcurrents implemented by a latch triggered by a bimetal responsive to I²R heating resulting from the overcurrent.

There is a growing interest in providing additional protection, and most importantly arc fault protection. Arc faults are typically high impedance faults and can be intermittent. Nevertheless, such arc faults can result in a fire.

Many non-aircraft circuit breakers employ ground fault protection. In aircraft applications, the aircraft frame is ground, and there is no neutral conductor. Some aircraft systems have also provided ground fault protection, but through the use of additional devices, namely current transformers which in some cases are remotely located from the protective relay.

Typically, aircraft circuit breaker panels are, at best, poor conductors (e.g., such panels are painted; are made of a non-conductive composite material; or are made of an oxidized conductive material, such as aluminum).

In order to monitor faults, such as arc faults in aircraft circuit breakers, there exists the need to power arc fault detection circuitry. Hence, there exists the need to provide a reliable ground connection to the aircraft circuit breaker in addition to providing the electrical connection to the line terminal from the power source.

U.S. Pat. No. 4,039,235 discloses a grounding strip for an electrical receptacle. The grounding strip includes an extension having screw-engaging means underlying an opening in the mounting ears of the receptacle. Metal screws, in turn, provide a self-grounded connection through the screw-engaging means to a grounded wall box.

U.S. Pat. No. 5,527,991 discloses a U-shaped metal grounding strap for a panel-mounted electrical switch. The grounding strap includes two legs having serrated segments, which scrape the edges of an opening in the panel in order to remove any paint or non-conductive coating on the panel.

U.S. Pat. No. 6,490,150 discloses a silver-plated copper strip grounding member sandwiched between an aircraft circuit breaker panel and an electrically conductive raised surface of a bezel of an aircraft circuit breaker. The electrically conductive raised surface is electrically engaged with the grounding member when a mounting nut is tightened. The grounding member is preferably made of a robust electrically conductive material under a wide range of conditions (e.g., copper, a suitable copper alloy, aluminum, or a suitable aluminum alloy any of which is plated with a suitable electrical conductor such as, for example, silver, tin, silver and tin, or gold). Preferably, the grounding member is suitably thin (e.g., about 0.020 in. thick), is placed under the aircraft circuit breaker panel, and is suitably mechanically attached (e.g., by a screw or rivet) to the lower surface of the panel.

U.S. Pat. No. 6,542,056 discloses an electronic arc fault circuit breaker including a panel mountable bezel. One end of a terminal is electrically connected to the bezel, and the other end of the terminal is electrically connected to a mating terminal of a printed circuit board, in order to provide a suitable external ground reference thereto.

There is room for improvement in methods of electrically grounding electrical switching apparatus, such as aircraft circuit breakers.

There is also room for improvement in electrical switching apparatus, such as aircraft circuit breakers.

### SUMMARY OF THE INVENTION

These needs and others are met by embodiments of the invention, which provide a ground to an electronic circuit of an electrical switching apparatus. A conductive member is coupled to the housing of the electrical switching apparatus. The conductive member comprises a first conductive portion structured to be electrically and mechanically coupled to a conductive panel and a plurality of second conductive portions having a plurality of openings therethrough. The electronic circuit comprises a number of printed circuit boards, each of which includes a plurality of conductive pads defining a ground. Each of the conductive pads has an opening therethrough. Each of a plurality of threaded conductive fasteners comprises a conductive end portion, a conductive shaft disposed from the conductive end portion, and a plurality of conductive threads disposed on the conductive shaft. A number of the plurality of conductive threads electrically and mechanically engage a corresponding one of the second conductive portions of the conductive member at a corresponding one of the openings thereof. The conductive end portion electrically engages a corresponding one of the conductive pads.

In accordance with one aspect of the invention, an electrical switching apparatus comprises: a housing; a conductive member coupled to the housing, the conductive member comprising a first conductive portion structured to be electrically and mechanically coupled to a conductive panel and a plurality of second conductive portions having a plurality of openings therethrough; separable contacts enclosed by the housing; an operating mechanism structured to open and close the separable contacts; an electronic circuit cooperating with the operating mechanism to trip open the separable contacts, the electronic circuit comprising a number of printed circuit boards, each of the number of printed circuit boards includes a plurality of conductive pads defining a ground, each of the conductive pads has an opening therethrough; and a plurality of threaded conductive fasteners, each of the plurality of threaded conductive fasteners comprises a conductive end portion, a conductive shaft disposed from the conductive end portion, and a plurality of conductive threads disposed on the conductive shaft, wherein a number of the plurality of conductive threads electrically and mechanically engage a corresponding one of the second conductive portions of the conductive member at a corresponding one of the openings thereof, and wherein the conductive end portion electrically engages a corresponding one of the conductive pads.

Each of the threaded conductive fasteners may comprise a conductive screw conductively threaded through a corresponding one of the pair of conductive mounting ears and a conductive nut threadably engaging the conductive screw.

The number of printed circuit boards may be two printed circuit boards; the conductive screw may be structured to provide a first compression electrical contact with one of the conductive pads of one of the two printed circuit boards; and the conductive nut may be structured to provide a second compression electrical contact with another one of the conductive pads of another one of the two printed circuit boards.

The housing may house epoxy encapsulating, for each of the threaded conductive fasteners, the conductive shaft and the number of the plurality of conductive threads electrically and mechanically engaging the corresponding one of the second conductive portions of the conductive member at the corresponding one of the openings thereof, and the conductive end portion electrically engaging the corresponding one of the conductive pads.

As another aspect of the invention, an electrical switching apparatus comprises: a housing; a conductive member coupled to the housing, the conductive member comprising a first conductive portion structured to be electrically and mechanically coupled to a conductive panel and two second conductive portions having two openings therethrough; separable contacts enclosed by the housing; an operating mechanism structured to open and close the separable contacts; an electronic circuit cooperating with the operating mechanism to trip open the separable contacts, the electronic circuit comprising two printed circuit boards, each of the two printed circuit boards includes two conductive pads defining a ground, each of the two conductive pads has an opening therethrough; and two threaded conductive fasteners, each of the two threaded conductive fasteners comprises a conductive end portion, a conductive shaft disposed from the conductive end portion, and a plurality of conductive threads disposed on the conductive shaft, wherein a number of the plurality of conductive threads electrically and mechanically engage a corresponding one of the two second conductive portions of the conductive member at a corresponding one of the two openings thereof, and wherein the conductive end portion electrically engages a corresponding one of the two conductive pads.

As another aspect of the invention, a method electrically grounds an electrical switching apparatus comprising a housing and an electronic trip circuit comprising a number of printed circuit boards, each of the number of printed circuit boards includes a plurality of conductive pads defining a ground, each of the conductive pads has an opening therethrough. The method comprises: grounding a conductive panel; coupling a conductive member to the housing of the electrical switching apparatus, the conductive member comprising a first conductive portion structured to be electrically and mechanically coupled to the conductive panel and a plurality of second conductive portions having a plurality of openings therethrough; employing a plurality of threaded conductive fasteners, each of the threaded conductive fasteners comprises a conductive end portion, a conductive shaft disposed from the conductive end portion, and a plurality of conductive threads disposed on the conductive shaft; for each of the plurality of threaded conductive fasteners, electrically and mechanically engaging a number of the plurality of conductive threads with a corresponding one of the second conductive portions of the conductive member at a corresponding one of the openings thereof; and for each of the plurality of threaded conductive fasteners, electrically engaging the conductive end portion with a corresponding one of the conductive pads.

The method may further comprise conductively threading a conductive screw of each of the threaded conductive fasteners through a corresponding one of the pair of conductive mounting ears; and threadably engaging the conductive screw with a conductive nut.

The method may further comprise employing as the number of printed circuit boards two printed circuit boards; providing a first compression electrical contact between the conductive screw and one of the conductive pads of one of the two printed circuit boards; and providing a second compression electrical contact between the conductive nut and another one of the conductive pads of another one of the two printed circuit boards.

### BRIEF DESCRIPTION OF THE DRAWINGS

A full understanding of the invention can be gained from the following description of the preferred embodiments when read in conjunction with the accompanying drawings in which:

FIG. 1 is an isometric view of a portion of an aircraft circuit breaker mounted to an aircraft panel in accordance with an embodiment of the invention.

FIG. 2 is an isometric view of the portion of the aircraft circuit breaker of FIG. 1.

FIG. 3 is a vertical elevation view of the portion of the aircraft circuit breaker of FIG. 1.

FIG. 4 is an end elevation view of the portion of the aircraft circuit breaker of FIG. 1.

FIG. 5 is a cross-sectional view along lines 5-5 of FIG. 1.

FIG. 6 is an isometric view of the aircraft circuit breaker of FIG. 1 with some parts cut away to show internal structures.

### DESCRIPTION OF THE PREFERRED EMBODIMENTS

As employed herein, the term “number” shall mean one or an integer greater than one (i.e., a plurality).

As employed herein, the term “bezel” means a panel mountable conductive mounting bushing of an electrical switching apparatus, such as an aircraft circuit breaker.

As employed herein, the term “fastener” means any suitable connecting or tightening mechanism expressly including, but not limited to, rivets, screws, bolts and the combinations of bolts and nuts (e.g., without limitation, lock nuts), and bolts, washers and nuts, as well as connecting mechanisms that do not require a separate fastening element (e.g., without limitation, a rivet; a screw; a bolt and a nut; a combination of bolts, washers and nuts).

As employed herein, the statement that two or more parts are “coupled” together shall mean that the parts are joined together either directly or joined through one or more intermediate parts.

As employed herein, the term “conductive pad” means a suitable conductive portion of a printed circuit board. For example, a conductive pad of a printed circuit board is a flat conductive surface used to make electrical contact with a number of electrical traces disposed on and/or within the printed circuit board and/or with a number of electrical devices and/or components disposed on or external to the printed circuit board.

The invention is described in association with an aircraft circuit breaker, although the invention is applicable to a wide range of electric switching apparatus, such as circuit interrupters.

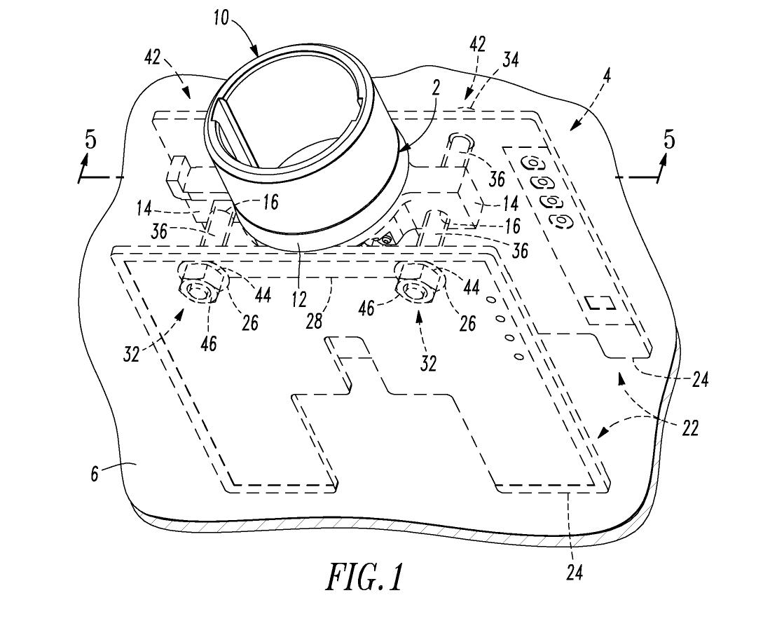

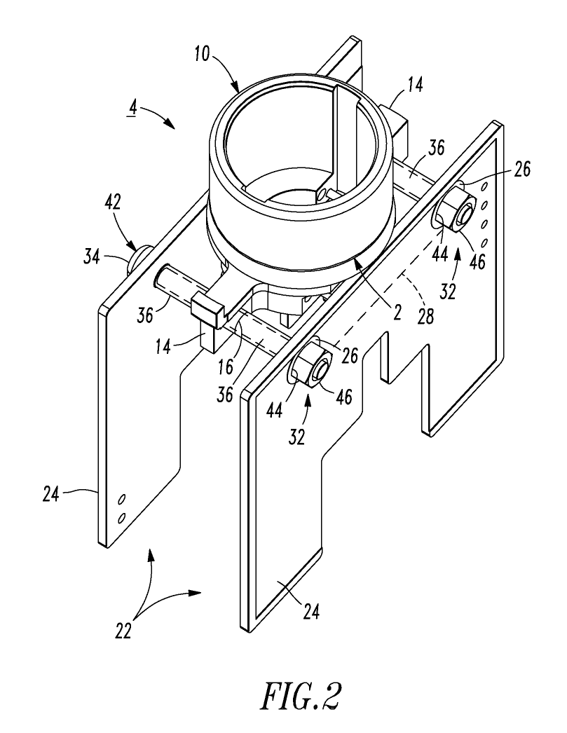

Referring to FIG. 1, a portion 2 of an electrical switching apparatus, such as the example aircraft circuit breaker 4 (predominantly shown in hidden line drawing), is mounted to a conductive panel, such as the example conductive aircraft panel 6.

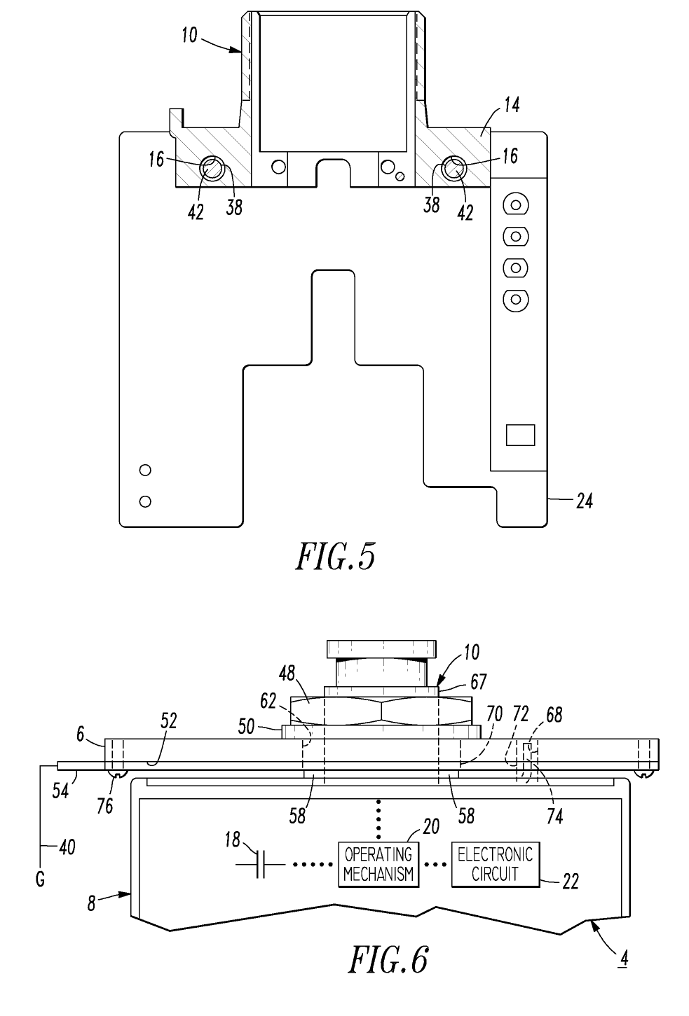

Also referring to FIG. 6, the circuit breaker 4 includes a housing 8 and a conductive member, such as the example panel mountable conductive mounting bushing 10, coupled to the housing 8. The conductive member 10 includes a first conductive portion 12 structured to be electrically and mechanically coupled to the aircraft panel 6 and a plurality of second conductive portions 14 (e.g., without limitation, a pair of conductive mounting ears 14 as best shown in FIG. 5) having a plurality of openings 16 therethrough.

As shown in FIG. 6, separable contacts 18 are enclosed by the housing 8. An operating mechanism 20 is structured to open and close the separable contacts 18. An electronic circuit 22 cooperates with the operating mechanism 20 to trip open the separable contacts 18. See, for example, U.S. Pat. No. 6,542,056, which is hereby incorporated by reference herein.

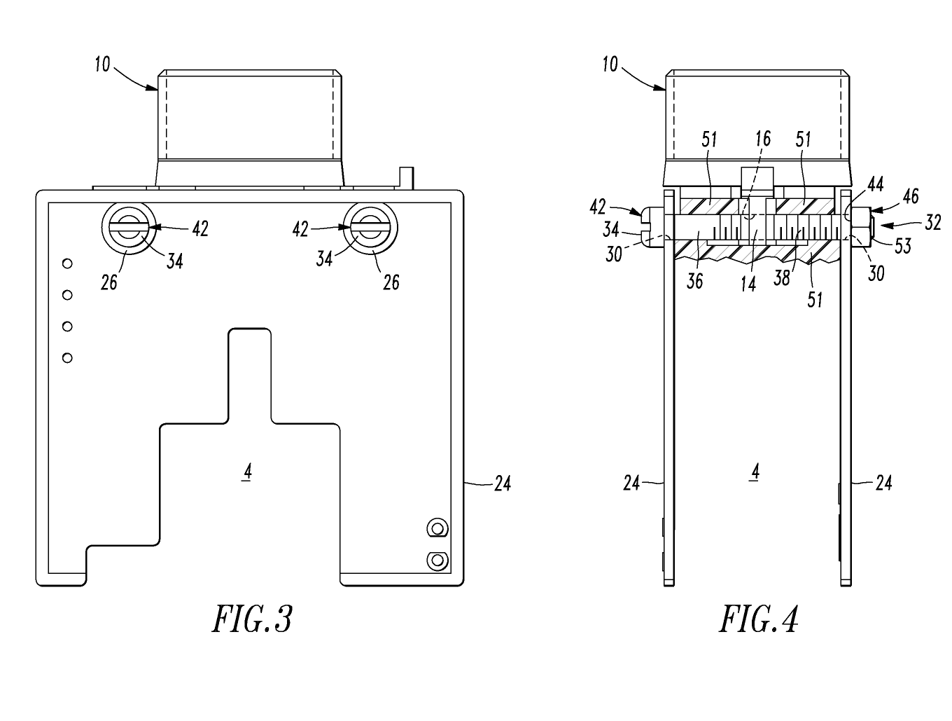

The electronic circuit 22 includes a number of printed circuit boards (PCBs) 24 (e.g., without limitation, two PCBs 24 are shown, although one or more PCBs may be employed). Each of the PCBs 24 includes a plurality of conductive pads 26 (e.g., without limitation, two conductive pads 26 are shown in each of FIGS. 1 and 3, although three or more conductive pads may be employed) defining a ground 28. Each of the conductive pads 26 has an opening 30 therethrough (as best shown in FIG. 4). Each one of a plurality of threaded conductive fasteners 32 (e.g., without limitation, two threaded conductive fasteners 32 are shown, although three or more threaded conductive fasteners may be employed) includes a conductive end portion 34, a conductive shaft threaded conductive fasteners 36 disposed from the conductive end portion 34, and a plurality of conductive threads 38 (best shown in FIG. 4) disposed on the conductive shaft 36. A number of the conductive threads 38 electrically and mechanically engage a corresponding one of the second conductive portions 14 of the conductive member 10 at a corresponding one of the openings 16 thereof. The conductive end portion 34 electrically engages a corresponding one of the conductive pads 26 (as best shown in FIG. 3).

A method of electrically grounding the circuit breaker 4 includes grounding the conductive aircraft panel 6 (as best shown in FIG. 6), coupling the conductive member 10 to the housing 8, employing a plurality of the threaded conductive fasteners 32, for each of the threaded conductive fasteners 32, electrically and mechanically engaging a number of the conductive threads 38 with a corresponding one of the second conductive portions 14 of the conductive member 10 at a corresponding one of the openings 16 thereof, and for each of the threaded conductive fasteners 32, electrically engaging the conductive end portion 34 with a corresponding one of the conductive pads 26.

As shown in FIG. 1, a ground member, such as a conductive member, such as the example conductive mounting bushing 10, is electrically connected to the internal electronic circuit ground 28 of the circuit breaker 4 by using the plural conductive fasteners 32. This avoids use of an internal or external wire (not shown) at the circuit breaker 4 or another conductor (not shown). This also avoids soldering a conductor, such as a wire (not shown), and; hence, avoids using flux or a flux cleaner (not shown). Therefore, there is no need to solder conductors, such as wires (not shown), point-to-point; to channel wires (not shown); or to dampen wires (not shown) from shock and vibration failure. An external conductor 40 (FIG. 6) is, however, electrically connected to, for example, the example aircraft panel 6.

### Example 1

As best shown in FIG. 4, each of the threaded conductive fasteners 32 is a conductive screw 42 conductively threaded through a corresponding one of the pair of conductive mounting ears 14 and a conductive nut 46 threadably engaging the conductive screw 42. In this example, the conductive mounting bushing 10 includes two example #0-80 openings 16 (only one opening 16 is shown in FIG. 4) through two example mounting ears 14 (only one ear 14 is shown in FIG. 4). Two example #0-80 conductive screws 42 (only one screw 42 is shown in FIG. 4) are conductively threaded through the conductive mounting bushing 10. The conductive end portion or head 34 of each conductive screw 42 and the flat 44 of a corresponding example #0-80 conductive jam nut 46 provide a compression electrical contact with the conductive pads 26 (FIGS. 1 and 3) on the two example PCBs 24. This provides a ground path from the electronic circuit 22 of both PCBs 24 to the conductive mounting bushing 10 and, ultimately, to the grounded aircraft panel 6 (FIGS. 1 and 6). The conductive mounting bushing 10 is electrically connected to the aircraft panel 6 in any conventional manner through, for example and without limitation, an example conductive nut 48 and conductive washer 50 as shown in FIG. 6.

### Example 2

The internals of the example circuit breaker 4 are preferably encapsulated within epoxy 51 (FIG. 4) to ensure longevity of the ground connections and the relatively low resistance thereof. As a non-limiting example, this permits the width of the circuit breaker 4 to be less than or equal to about 0.620″, which is desired for direct retrofit in fighter and helicopter applications (not shown).

For example, the housing 8 (FIG. 6) may house epoxy 51 (FIG. 4) encapsulating, for each of the threaded conductive fasteners 32, the conductive shaft 36 and a number of the conductive threads 38 electrically and mechanically engaging the corresponding one of the second conductive portions 14 of the conductive member 10 at the corresponding one of the openings 16 thereof, and the conductive end portion 34 electrically engaging the corresponding one of the conductive pads 26 (FIG. 3).

### Example 3

Preferably, the various conductive components, such as the conductive mounting bushing 10, the conductive screws 42 and the conductive jam nuts 46 are made from brass for suitable current carrying resistance, corrosion resistance, and the ability to be plated with cadmium to meet suitable galvanic compatibility specifications. Although not required, the cadmium preferably includes a black die to comply with the mounting bushing 10 being black in color (e.g., for glare and/or Night Vision Imaging System (NVIS) compatibility).

### Example 4

Preferably, the resistance between the conductive mounting bushing 10 and the internal electronic circuit ground 28 (FIG. 1) of the electronic circuit 22 (FIG. 6) of the circuit breaker 4 is less than or equal to about 300 milliohms.

### Example 5

A probe of a handheld meter (not shown) can conveniently be electrically attached to the head 34 of the conductive screw 42 or to the conductive jam nut 46, in order to measure, for example, the electrical resistance of the resulting ground connections.

### Example 6

Preferably, a silver epoxy 53 is applied over the conductive screws 42 and conductive jam nuts 46 (e.g., about where the conductive nut 46 threadably engages the conductive screw 42). This provides a suitable tamper proof electrical and mechanical connection and an additional path of electrical conductivity, while avoiding the need to use LOCTITE® or another locking mechanism.

### Example 7

The conductive mounting bushing 10 can be made, for example and without limitation, by any suitable technique, such as machining, die casting, or metal injection molding. If metal injection molding is employed, then preferably the resulting component is cadmium plated for electrical conductivity and galvanic compatibility to the conductive (e.g., aluminum) aircraft panel 6.

### Example 8

As best shown in FIG. 4, the conductive screw 42 is preferably structured to provide a first compression electrical contact with one of the conductive pads 26 (FIG. 3) of one of the two example PCBs 24. The conductive nut 46 is preferably structured to provide a second compression electrical contact with another one of the conductive pads 26 (FIG. 1) of another one of the two example PCBs 24.

### Example 9

FIG. 6 shows an example of grounding the aircraft panel 6, which has a surface 52. See, for example, U.S. Pat. No. 6,490,150, which is hereby incorporated by reference herein. A ground conductor 40 grounds (G) an electrically conductive grounding member 54. A circuit interrupter, such as the example aircraft circuit breaker 4 has an electrically conductive surface 58 on the panel mountable conductive mounting bushing 10 (e.g., bezel). The electrically conductive grounding member 54 is disposed between the panel surface 52 and the electrically conductive circuit breaker surface 58.

The example panel 6 has an opening 62 corresponding to the circuit breaker bezel 10, which passes through that opening 62. In turn, a suitable fastener, such as the conductive lock washer 50 and conductive nut 48, are employed on a threaded portion 67 of the bezel 10 to mount the circuit breaker 4 to the panel 6. When the mounting nut 48 is tightened, the electrically conductive surface 58 suitably electrically engages the electrically conductive grounding member 54. Preferably, the grounding member 54 is sandwiched between the panel 6 and the circuit breaker surface 58.

The grounding member 54 is preferably made of a robust electrically conductive material under a wide range of conditions (e.g., copper, a suitable copper alloy, aluminum, or a suitable aluminum alloy any of which is plated with a suitable electrical conductor such as, for example, silver, tin, silver and tin, or gold). Preferably, the electrically conductive grounding member 54 is a silver-plated copper grounding strip 54, the bezel 10 is preferably made of copper, and the electrically conductive surface 58 is a silver-plated copper surface.

The panel 6 also has a second opening 68 proximate the first opening 62. The electrically conductive grounding member 54 has a first opening 70 corresponding to the bezel 10 and a second opening 72 proximate the first opening 70 thereof. The generally cylindrical bezel 10 passes through the first opening 70 of the electrically conductive grounding member 54 and the first panel opening 62. The circuit breaker 4 has a raised portion or stop 74 proximate the bezel 10. The stop 74 passes through the second opening 72 of the electrically conductive grounding member 54 and the second panel opening 68, thereby preventing rotation of the mounted circuit breaker 4 when installed in the panel 6.

The holes 70,72 of the grounding member 54 preferably mimic the corresponding holes 62,68, respectively, of the mounting panel 6. Preferably, the grounding member 54 is suitably thin (e.g., about 0.020 in. thick in the example embodiment), is placed under the mounting panel 6, and is suitably mechanically attached (e.g., by a screw or rivet 76) to the surface 52 of the mounting panel 6.

In the example embodiment, the bezel 10 is preferably made of a suitable copper alloy (e.g., brass), copper, a suitable aluminum alloy, or aluminum having a suitably plated (e.g., plated with a robust electrically conductive material under a wide range of conditions, such as silver, tin, silver and tin, gold) and suitably raised surface 58.

While specific embodiments of the invention have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of the invention which is to be given the full breadth of the claims appended and any and all equivalents thereof.

What is claimed is:

1. An electrical switching apparatus comprising:
a housing;
a conductive member coupled to said housing, said conductive member comprising a first conductive portion structured to be electrically and mechanically coupled to a conductive panel and a plurality of second conductive portions having a plurality of openings therethrough;
separable contacts enclosed by said housing;
an operating mechanism structured to open and close said separable contacts;
an electronic circuit cooperating with said operating mechanism to trip open said separable contacts, said electronic circuit comprising a number of printed circuit boards, each of said number of printed circuit boards including a plurality of conductive pads defining a ground, each of said conductive pads having an opening therethrough; and
a plurality of threaded conductive fasteners, each of said plurality of threaded conductive fasteners comprising a conductive end portion, a conductive shaft disposed from said conductive end portion, and a plurality of conductive threads disposed on said conductive shaft,
wherein a number of said plurality of conductive threads electrically and mechanically engage a corresponding one of the second conductive portions of said conductive member at a corresponding one of the openings thereof, and
wherein said conductive end portion electrically engages a corresponding one of said conductive pads.

2. The electrical switching apparatus of claim 1 wherein said conductive member is a panel mountable conductive mounting bushing.

3. The electrical switching apparatus of claim 1 wherein said conductive panel has an opening; and wherein the first conductive portion of said conductive member comprises a generally cylindrical bezel portion structured to pass through the opening of said conductive panel.

4. The electrical switching apparatus of claim 1 wherein the second conductive portions of said conductive member are a pair of conductive mounting ears.

5. The electrical switching apparatus of claim 4 wherein each of said threaded conductive fasteners comprises a conductive screw conductively threaded through a corresponding one of said pair of conductive mounting ears and a conductive nut threadably engaging said conductive screw.

6. The electrical switching apparatus of claim 5 wherein said number of printed circuit boards is two printed circuit boards; wherein said conductive screw is structured to provide a first compression electrical contact with one of said conductive pads of one of said two printed circuit boards; and wherein said conductive nut is structured to provide a second compression electrical contact with another one of said conductive pads of another one of said two printed circuit boards.

7. The electrical switching apparatus of claim 5 wherein said conductive mounting bushing, said conductive screw and said conductive nut are made from brass.

8. The electrical switching apparatus of claim 5 wherein said conductive mounting bushing, said conductive screw and said conductive nut are made from brass plated with cadmium.

9. The electrical switching apparatus of claim 5 wherein said conductive screw and said conductive nut both have silver epoxy applied about where said conductive nut threadably engages said conductive screw.

10. The electrical switching apparatus of claim 1 wherein said housing houses epoxy encapsulating, for each of said threaded conductive fasteners, the conductive shaft and said number of said plurality of conductive threads electrically and mechanically engaging the corresponding one of the second conductive portions of said conductive member at the corresponding one of the openings thereof, and the conductive end portion electrically engaging the corresponding one of said conductive pads.

11. The electrical switching apparatus of claim 1 wherein the electrical resistance between said conductive member and the ground of said electronic circuit is less than or equal to about 300 milliohms.

12. The electrical switching apparatus of claim 1 wherein said conductive panel comprises a circuit interrupter conductive panel and a silver-plated copper strip grounding member; wherein said first conductive portion comprises a conductive raised surface structured to be electrically and mechanically engaged with said silver-plated copper strip grounding member; and wherein said silver-plated copper strip grounding member is structured to be sandwiched between said conductive raised surface and said circuit interrupter conductive panel.

13. The electrical switching apparatus of claim 1 wherein said conductive panel comprises a circuit interrupter conductive panel and a grounding member; wherein said first conductive portion comprises a conductive surface structured to be electrically and mechanically engaged with said grounding member; and wherein said grounding member is structured to be sandwiched between said conductive surface and said circuit interrupter conductive panel.

14. An electrical switching apparatus comprising:
a housing;
a conductive member coupled to said housing, said conductive member comprising a first conductive portion structured to be electrically and mechanically coupled to a conductive panel and two second conductive portions having two openings therethrough;
separable contacts enclosed by said housing;
an operating mechanism structured to open and close said separable contacts;
an electronic circuit cooperating with said operating mechanism to trip open said separable contacts, said electronic circuit comprising two printed circuit boards, each of said two printed circuit boards including two conductive pads defining a ground, each of said two conductive pads having an opening therethrough; and
two threaded conductive fasteners, each of said two threaded conductive fasteners comprising a conductive end portion, a conductive shaft disposed from said conductive end portion, and a plurality of conductive threads disposed on said conductive shaft,
wherein a number of said plurality of conductive threads electrically and mechanically engage a corresponding one of the two second conductive portions of said conductive member at a corresponding one of the two openings thereof, and
wherein said conductive end portion electrically engages a corresponding one of said two conductive pads.

15. The electrical switching apparatus of claim 14 wherein the two conductive portions of said conductive member are a pair of conductive mounting ears.

16. The electrical switching apparatus of claim 15 wherein each of said two threaded conductive fasteners comprises a conductive screw conductively threaded through a corresponding one of said pair of conductive mounting ears and a conductive nut threadably engaging said conductive screw; wherein said conductive screw is structured to provide a first compression electrical contact with one of said two conductive pads of one of said two printed circuit boards; and wherein said conductive nut is structured to provide a second compression electrical contact with another one of said two conductive pads of another one of said two printed circuit boards.

17. A method of electrically grounding an electrical switching apparatus comprising a housing and an electronic trip circuit comprising a number of printed circuit boards, each of said number of printed circuit boards including a plurality of conductive pads defining a ground, each of said conductive pads having an opening therethrough, said method comprising:
grounding a conductive panel;
coupling a conductive member to the housing of said electrical switching apparatus, said conductive member comprising a first conductive portion structured to be electrically and mechanically coupled to said conductive panel and a plurality of second conductive portions having a plurality of openings therethrough;
employing a plurality of threaded conductive fasteners, each of said threaded conductive fasteners comprising a conductive end portion, a conductive shaft disposed from said conductive end portion, and a plurality of conductive threads disposed on said conductive shaft;
for each of said plurality of threaded conductive fasteners, electrically and mechanically engaging a number of said plurality of conductive threads with a corresponding one of the second conductive portions of said conductive member at a corresponding one of the openings thereof, and
for each of said plurality of threaded conductive fasteners, electrically engaging said conductive end portion with a corresponding one of said conductive pads.

18. The method of claim 17 further comprising
employing as said conductive member a panel mountable conductive mounting bushing.

19. The method of claim 17 further comprising
employing said conductive panel having an opening;
including with the first conductive portion of said conductive member a generally cylindrical bezel portion; and
passing said generally cylindrical bezel portion through the opening of said conductive panel.

20. The method of claim 17 further comprising
employing as the second conductive portions of said conductive member a pair of conductive mounting ears.

21. The method of claim 20 further comprising
conductively threading a conductive screw of each of said threaded conductive fasteners through a corresponding one of said pair of conductive mounting ears; and
threadably engaging said conductive screw with a conductive nut.

22. The method of claim 21 further comprising
employing as said number of printed circuit boards two printed circuit boards;
providing a first compression electrical contact between said conductive screw and one of said conductive pads of one of said two printed circuit boards; and
providing a second compression electrical contact between said conductive nut and another one of said conductive pads of another one of said two printed circuit boards.
